(19) United States
(12) Patent Application Publication
(10) Pub. No.: US 2003/0215997 A1
(43) Pub. Date: Nov. 20, 2003

(54) Method of manufacturing semiconductor device

(75) Inventors: Atsushi Hachisuka, Tokyo (JP); Atsushi Amo, Tokyo (JP); Tatsuo Kasaoka, Tokyo (JP); Shunji Kubo, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/261,672

(22) Filed: Oct. 2, 2002

(30) Foreign Application Priority Data
May 17, 2002 (JP) 2002-142861

(51) Int. Cl. H01L 21/8234; H01L 21/8244; H01L 21/8242

(52) U.S. Cl. 438/241

(57) ABSTRACT

It is an object to provide a semiconductor technique for shortening a time required for manufacturing a semiconductor device of a memory and logic mixing type. Contact plugs (17) and (67) are formed in an interlayer insulating film (14) and stopper films (13) and (15) with an upper surface thereof exposed from the stopper film (15). Then, an interlayer insulating film (18) is formed on the stopper film (15) and the contact plugs (17) and (67), and an opening portion (69) for exposing the contact plug (67) is formed in the interlayer insulating film (18). By etching only the interlayer insulating film (18) without etching the stopper film (15), the opening portion (69) can be formed. Consequently, it is possible to shorten a time required for forming the opening portion (69).

### BACKGROUND OF THE INVENTION

1. Field of the Invention

The present invention relates to a method of manufacturing a semiconductor device of a memory and logic mixing type in which a memory device and a logic device are formed on a semiconductor substrate.

2. Description of the Background Art

FIGS. 16 to 28 are sectional views showing a conventional method of manufacturing a semiconductor device of a memory and logic mixing type in order of steps. In the semiconductor device of a memory and logic mixing type according to the conventional art, a DRAM including a memory cell having a CUB (Capacitor Under Bit line) structure is employed as a memory device, for example, and a Dual Gate salicide CMOS transistor is employed as a logic device, for example.

With reference to FIG. 16, first of all, an element isolation insulating film 2 is formed in an upper surface of a semiconductor substrate 1 to be an n-type silicon substrate, for example, by a well known LOCOS isolation technique or trench isolation technique. Then, p-type well regions 3 and 53 and an n-type well region 54 are formed in the upper surface of the semiconductor substrate 1. More specifically, the well region 53 is formed in the upper surface of the semiconductor substrate 1 in a region in which a memory device is to be formed (which will be hereinafter referred to as a “memory formation region”) and the well region 54 is formed in a bottom portion thereof. Moreover, the well region 3 is formed in the upper surface of the semiconductor substrate 1 in a region in which a logic device is to be formed (which will be hereinafter referred to as a “logic formation region”). Then, channel injection is carried out.

Next, a plurality of gate structures 61 are formed apart from each other by a predetermined distance on the semiconductor substrate 1 in the memory formation region. Each of the gate structures 61 has such a structure that a gate insulating film 55 for which a silicon oxide film is employed, for example, a gate electrode 56 for which a polycrystalline silicon film is employed, for example, and a silicon oxide film 57 for which a TEOS film is employed, for example, are stacked in this order. Moreover, a plurality of gate structures 11 are formed apart from each other by a predetermined distance on the semiconductor substrate 1 in the logic formation region. Each of the gate structures 11 has such a structure that a gate insulating film 5 for which a silicon oxide film is employed, for example, a gate electrode 6 for which a polycrystalline silicon film is employed, for example, and a silicon oxide film 7 for which a TEOS film is employed, for example, are stacked in this order.

Using the gate structures 11 and 61 and the element isolation insulating film 2 as masks, then, impurities such as phosphorus or arsenic are ion implanted into the upper surface of the semiconductor substrate 1 in a comparatively low concentration. Consequently, n⁻ type impurity regions 58a are formed in the upper surface of the semiconductor substrate 1 in the memory formation region, and furthermore, n⁻ type impurity regions 8a are formed in the upper surface of the semiconductor substrate 1 in the logic formation region.

With reference to FIG. 17, next, a silicon nitride film is formed over the whole surface by a CVD method, for example, and the silicon nitride film is then etched by anisotropic dry etching having a high etching rate in a direction of a depth of the semiconductor substrate 1. Consequently, a side wall 60 is formed on a side surface of the gate structure 61 and a side wall 10 is formed on a side surface of the gate structure 11.

Using the gate structures 11 and 61, the element isolation insulating film 2 and the side walls 10 and 60 as masks, thereafter, impurities such as phosphorus or arsenic are ion implanted into the upper surface of the semiconductor substrate 1 in a comparatively high concentration. Consequently, n⁺ type impurity regions 58b are formed in the upper surface of the semiconductor substrate 1 in the memory formation region, and furthermore, n⁺ type impurity regions 8b are formed in the upper surface of the semiconductor substrate 1 in the logic formation region.

By the steps described above, a plurality of source/drain regions 59 constituted by the impurity regions 58a and 58b respectively are formed apart from each other by a predetermined distance in the upper surface of the semiconductor substrate 1 in the memory formation region, and furthermore, the gate structure 61 is formed on the upper surface of the semiconductor substrate 1 between the source/drain regions 59 provided adjacently to each other. Moreover, a plurality of source/drain regions 9 constituted by the impurity regions 8a and 8b respectively are formed apart from each other by a predetermined distance in the upper surface of the semiconductor substrate 1 in the logic formation region, and furthermore, the gate structure 11 is formed on the upper surface of the semiconductor substrate 1 between the source/drain regions 9 provided adjacently to each other.

For the following reasons, the impurity regions 8b and 58b are formed more deeply than the impurity regions 8a and 58a. More specifically, in formation of a cobalt silicide film 12 which will be described below on the semiconductor substrate 1, the cobalt silicide film 12 is formed partially deeply in some cases. In order to avoid an electrical connection of the cobalt silicide film 12 to the well regions 3 and 53, the impurity regions 8b and 58b are formed more deeply than the impurity regions 8a and 58a. At this time, if the concentration of the impurity region 58b is too high, a leakage current in a direction of a channel is increased. For this reason, an electric charge holding characteristic (also referred to as a “Refresh characteristic”) of the memory device is deteriorated in some cases. In order to prevent the deterioration, the concentration of the impurity region 58b in the memory formation region is set to be lower than that of the impurity region 8b in the logic formation region.

With reference to FIG. 18, next, the silicon oxide film 57 of the gate structure 61 and the silicon oxide film 7 of the gate structure 11 are removed by using hydrofluoric acid, for example.

With reference to FIG. 19, then, a cobalt film is formed over the whole surface by sputtering, for example. Thereafter, a heat treatment is carried out by using a lamp annealing device, for example, thereby causing cobalt to react to silicon provided in contact therewith. Consequently, the upper surface of the semiconductor substrate 1 is partially silicided so that the cobalt silicide film 12 is formed on the source/drain regions 9 and 59. At the same time, upper surfaces of the gate electrodes 6 and 56 are silicided so that the cobalt silicide film 12 is formed thereon. As a result, the gate structure 11 having the cobalt silicide film 12 on the gate electrode 6 and the gate structure 61 having the cobalt silicide film 12 on the gate electrode 56 are formed. Subsequently, the unreacted cobalt film is removed.

With reference to FIG. 20, next, a stopper film 13 for which a silicon nitride film is employed, for example, is formed over the whole surface. Then, an interlayer insulating film 14 for which a BPTEOS film is employed, for example, is formed on the stopper film 13 and is then flattened by a CMP method or the like. As a result, the flat interlayer insulating film 14 is formed on the semiconductor substrate 1.

With reference to FIG. 21, thereafter, contact plugs 116 and 166 are formed in the interlayer insulating film 14 and the stopper film 13. Each of the contact plugs 116 is electrically connected to the semiconductor substrate 1 in the logic formation region through the cobalt silicide film 12, and an upper surface thereof is exposed from the interlayer insulating film 14. Moreover, each of the contact plugs 166 is electrically connected to the semiconductor substrate 1 in the memory formation region through the cobalt silicide film 12, and an upper surface thereof is exposed from the interlayer insulating film 14. A method of manufacturing the contact plugs 116 and 166 will be specifically described below.

First of all, a photoresist (not shown) having a predetermined opening pattern is formed on the interlayer insulating film 14 by photolithography. Using the photoresist as a mask, then, the interlayer insulating film 14 is etched with the stopper film 13 serving as an etching stopper to be removed. At this time, anisotropic dry etching using a mixed gas of C₅F₈, O₂ and Ar is employed for the etching.

Thereafter, the photoresist is removed and the exposed stopper film 13 is etched and removed. At this time, anisotropic dry etching using a mixed gas of CHF₃, O₂ and Ar is employed for the etching. Consequently, contact holes 165 reaching the cobalt silicide film 12 provided on the semiconductor substrate 1 in the memory formation region and contact holes 115 reaching the cobalt silicide film 12 provided on the semiconductor substrate 1 in the logic formation region are formed in the interlayer insulating film 14 and the stopper film 13.

Next, a laminated film comprising a barrier metal layer formed of titanium nitride, for example, and a refractory metal layer formed of titanium, tungsten or the like, is provided over the whole surface. Then, the laminated film provided on an upper surface of the interlayer insulating film 14 is removed by using the CMP method. Consequently, the contact plugs 116 each formed by the barrier metal layer and the refractory metal layer and filling the contact hole 115 are provided, and the contact plugs 166 each formed by the barrier metal layer and the refractory metal layer and filling the contact hole 165 are provided. As a result, the source/drain region 59 and the contact plug 166 are electrically connected to each other, and the source/drain region 9 and the contact plug 116 are electrically connected to each other. A contact plug connected electrically to the gate electrode 56 or the gate electrode 6 through the cobalt silicide film 12 is formed in the interlayer insulating film 14 and the stopper film 13, which is not shown.

With reference to FIG. 22, next, a stopper film 117 for which a silicon nitride film is employed, for example, is formed on the interlayer insulating film 14 and the contact plugs 116 and 166.

With reference to FIG. 23, next, an interlayer insulating film 118 is formed on the stopper film 117. For example, a BPTEOS film is employed for the interlayer insulating film 118. Then, a photoresist (not shown) having a predetermined opening pattern is formed on the interlayer insulating film 118. Using the photoresist as a mask, the interlayer insulating film 118 is etched with the stopper film 117 serving as an etching stopper to be removed. At this time, the anisotropic dry etching using a mixed gas of C₅F₈, O₂ and Ar is employed for the etching.

Thereafter, the photoresist is removed and the exposed stopper film 117 is etched and removed. At this time, the anisotropic dry etching using a mixed gas of CHF₃, O₂ and Ar is employed for the etching. Consequently, opening portions 169 for exposing some of the contact plugs 166 are formed in the interlayer insulating film 118 and the stopper film 117.

Next, a capacitor of a DRAM memory cell is formed in contact with the contact plug 166 in each of the opening portions 169. More specifically, with reference to FIG. 24, a metal film containing a refractory metal such as ruthenium is first formed over the whole surface. Then, the opening portions 169 are covered with a photoresist (not shown) and the metal film provided on an upper surface of the interlayer insulating film 118 is removed by the anisotropic dry etching. Consequently, a lower electrode 170 of the capacitor containing the refractory metal such as ruthenium is formed in each of the opening portions 169. While the metal film formed on the upper surface of the interlayer insulating film 118 is removed by the anisotropic dry etching, the metal film may be removed by using the CMP method.

With reference to FIG. 25, subsequently, an insulating film formed of tantalum pentoxide and a metal film containing the refractory metal such as ruthenium are stacked over the whole surface in this order, and they are then subjected to patterning using a photoresist. Consequently, a dielectric film 171 of a capacitor which is formed of tantalum pentoxide and an upper electrode 172 of a capacitor which contains the refractory metal such as ruthenium are provided so that the capacitor is completely formed in each of the opening portions 169.

With reference to FIG. 26, subsequently, an interlayer insulating film 123 for which a TEOS film is employed, for example, is formed on the upper electrodes 172 of the capacitors and the interlayer insulating film 118, and is flattened by the CMP method. Then, contact holes 124 and 174 are formed in the interlayer insulating films 118 and 123 and the stopper film 117. Each of the contact holes 124 reaches the contact plug 116 from an upper surface of the interlayer insulating film 123. Each of the contact holes 174 reaches the contact plug 166 which does not contact with the capacitor from the upper surface of the interlayer insulating film 123.

When the contact holes 124 and 174 are to be formed, first of all, the interlayer insulating films 118 and 123 are etched with the stopper film 117 serving as an etching stopper to be removed, using a photoresist (not shown) having a predetermined opening pattern. At this time, the anisotropic dry etching using a mixed gas of CHF₃, O₂ and Ar is employed for the etching. Then, the photoresist is removed and the exposed stopper film 117 is removed by the etching. At this time, the anisotropic dry etching using a mixed gas of C₅F₈, O₂ and Ar is employed for the etching. The interlayer insulating film 123 is also provided with a contact hole reaching the upper electrode 172 from the upper surface thereof, which is not shown.

With reference to FIG. 27, next, a laminated film comprising a barrier metal layer formed of titanium nitride, for example, and a refractory metal layer formed of titanium, tungsten or the like, is provided over the whole surface. Then, the laminated film provided on the upper surface of the interlayer insulating film 123 is removed by using the CMP method. Consequently, a contact plugs 125 each formed by the barrier metal layer and the refractory metal layer and filling the contact hole 124 are provided, and a contact plugs 175 each formed by the barrier metal layer and the refractory metal layer and filling in the contact hole 174 are provided.

With reference to FIG. 28, subsequently, the interlayer insulating film 123 is provided with a wiring 129 in contact with the contact plug 125 and a wiring 179 in contact with the contact plug 175. The wiring 129 has such a structure that an aluminum wiring 127 is vertically interposed between titanium nitride layers 126 and 128. Moreover, the wiring 179 also has such a structure that an aluminum wiring 177 is vertically interposed between titanium nitride layers 176 and 178 in the same manner as the wiring 129.

By the steps described above, the memory device is formed in the memory formation region and the logic device is formed in the logic formation region.

As described above, in the method of manufacturing the semiconductor device according to the conventional art, when the opening portion 169 is to be formed (see FIG. 23) or the contact holes 115, 165, 124 and 174 are to be formed (see FIGS. 21 and 26), the interlayer insulating film is etched with the stopper film serving as an etching stopper and the stopper film is then etched. At this time, when the interlayer insulating film is etched by using the mixed gas described above, a fluorocarbon based (CxFy) deposition film is provided on the upper surface of the stopper film. By generating the deposition film, it is possible to enhance selectivity for the stopper film when etching the interlayer insulating film.

When the stopper film is etched in such a state that the deposition film is provided on the stopper film, the deposition film acts as a mask so that the stopper film cannot be etched normally. In order to eliminate the drawback, the step of removing the photoresist is carried out before the stopper film is etched, and the deposition film is removed at the same step.

In the process for manufacturing the semiconductor device according to the conventional art, thus, it is necessary to carry out the step of etching the interlayer insulating film and the step of etching the stopper film when forming the opening portion 169 or the contact holes 115, 165, 124 and 174. Between these steps, the step of removing the photoresist is required. For this reason, it is necessary to change a manufacturing device from an etching system to an ashing system or from the ashing system to the etching system when forming the opening portion 169 or the contact holes 115, 165, 124 and 174. As a result, a time for manufacturing the semiconductor device is taken.

### SUMMARY OF THE INVENTION

It is an object of the present invention to provide a semiconductor technique for shortening a time required for manufacturing a semiconductor device of a memory and logic mixing type.

According to a first aspect of the present invention, a method of manufacturing a semiconductor device includes the following steps (a) to (h). The step (a) is to prepare a semiconductor substrate having a first region in which a memory device is to be formed and a second region in which a logic device is to be formed, and the step (b) is to form a first interlayer insulating film on the semiconductor substrate. The step (c) is to form a stopper film on the first interlayer insulating film, and the step (d) is to form, in the first interlayer insulating film and the stopper film, a first contact plug connected electrically to the semiconductor substrate in the first region and having an upper surface exposed from the stopper film and a second contact plug connected electrically to the semiconductor substrate in the second region and having an upper surface exposed from the stopper film. The step (e) is to form a second interlayer insulating film on the stopper film and the first and second contact plugs, and the step (f) is to etch the second interlayer insulating film with the stopper film and the first contact plug serving as an etching stopper, thereby forming an opening portion for exposing the first contact plug in the second interlayer insulating film. The step (g) is to form a capacitor in contact with the first contact plug in the opening portion, and the step (h) is to etch the second interlayer insulating film with the stopper film and the second contact plug serving as an etching stopper, thereby forming a first contact hole reaching the second contact plug in the second interlayer insulating film.

When executing the steps (f) and (h), only the interlayer insulating film is etched and the step of etching the stopper film is not carried out. Consequently, it is possible to shorten a time required for manufacturing the semiconductor device.

According to a second aspect of the present invention, a method of manufacturing a semiconductor device includes the following steps (a) to (g). The step (a) is to prepare a semiconductor substrate having a first region in which a memory device is to be formed and a second region in which a logic device is to be formed, and the step (b) is to form a first interlayer insulating film on the semiconductor substrate. The step (c) is to form, in the first interlayer insulating film, a first contact plug connected electrically to the semiconductor substrate in the first region and having an upper surface exposed from the first interlayer insulating film and a second contact plug connected electrically to the semiconductor substrate in the second region and having an upper surface exposed from the first interlayer insulating film, and the step (d) is to form a second interlayer insulating film on the first interlayer insulating film and the first and second contact plugs. The step (e) is to etch the second interlayer insulating film, thereby forming an opening portion for exposing the first contact plug on the second interlayer insulating film, and the step (f) is to form a capacitor in contact with the first contact plug in the opening portion. The step (g) is to etch the second interlayer insulating film, thereby forming a first contact hole reaching the second contact plug in the second interlayer insulating film.

When executing the steps (e) and (g), only the interlayer insulating film is etched and the step of etching the stopper film is not carried out. Consequently, it is possible to shorten a time required for manufacturing the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 8 are sectional views showing a method of manufacturing a semiconductor device according to a first embodiment of the present invention in order of steps,

FIGS. 9 to 15 are sectional views showing a method of manufacturing a semiconductor device according to a second embodiment of the present invention in order of steps,

FIGS. 16 to 20 are sectional views showing methods of manufacturing a semiconductor device according to the conventional art and the first and second embodiments of the present invention in order of steps, and

FIGS. 21 to 28 are sectional views showing the method of manufacturing a semiconductor device according to the conventional art in order of steps.

### DESCRIPTION OF THE PREFERRED EMBODIMENTS

First Embodiment

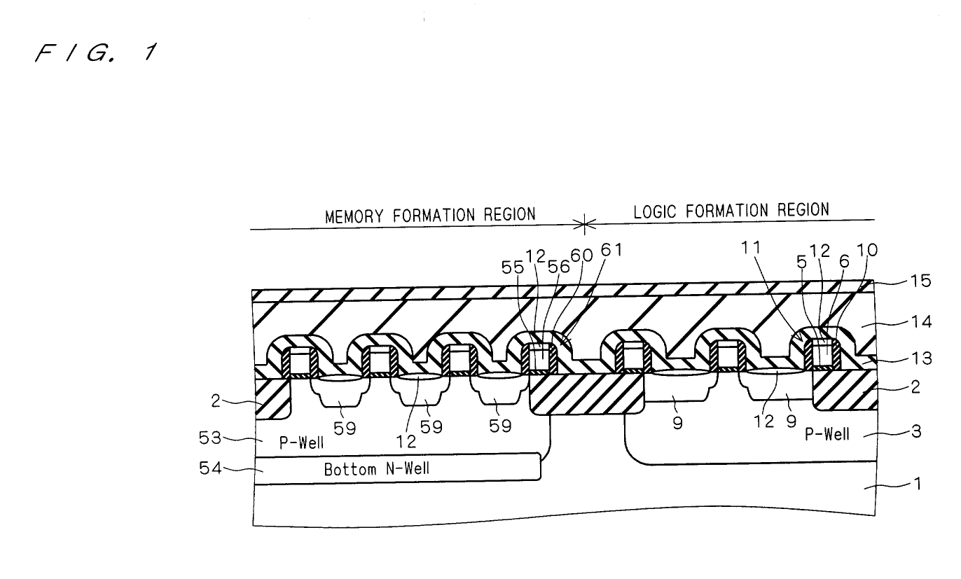

FIGS. 1 to 8 are sectional views showing a method of manufacturing a semiconductor device according to a first embodiment of the present invention in order of steps. The semiconductor device according to the first embodiment is of a memory and logic mixing type, and a DRAM including a memory cell having a CUB structure is employed for a memory device, for example, and a Dual Gate salicide CMOS transistor is employed for a logic device, for example. With reference to FIGS. 1 to 8, the method of manufacturing a semiconductor device according to the first embodiment will be described below.

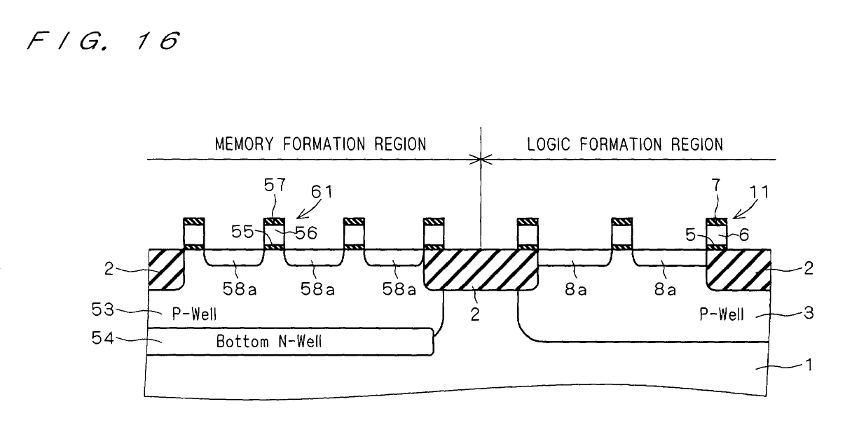

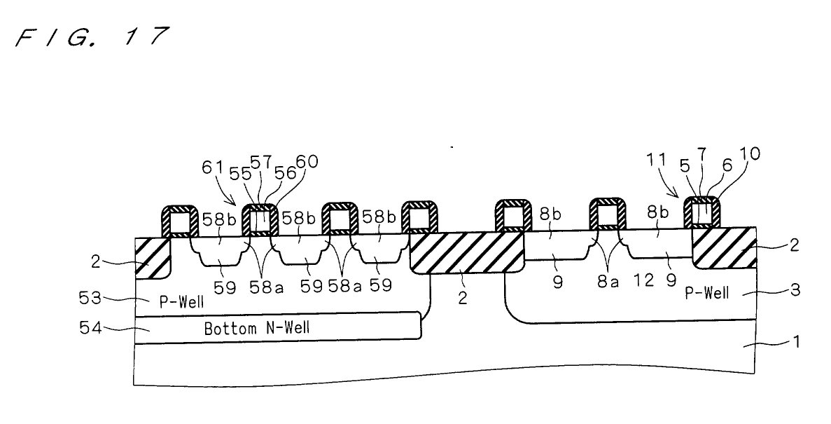

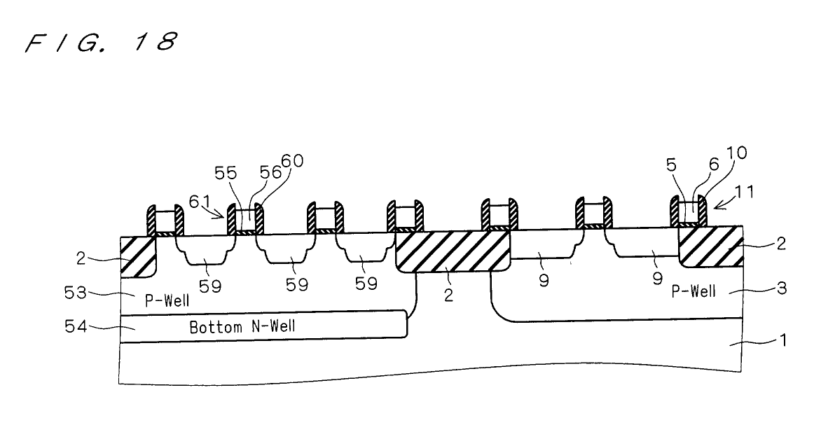

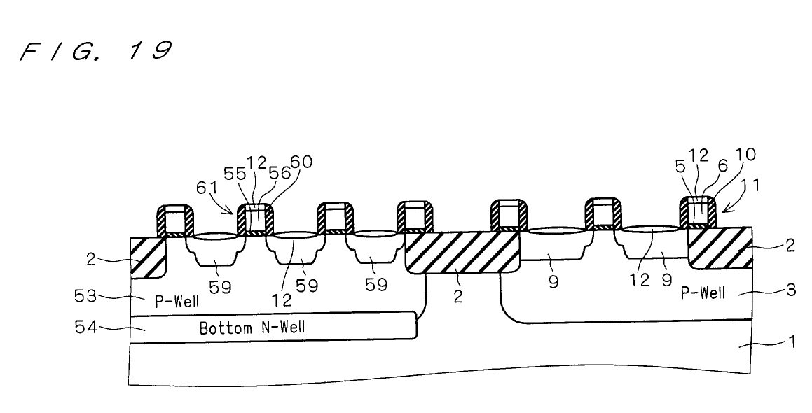

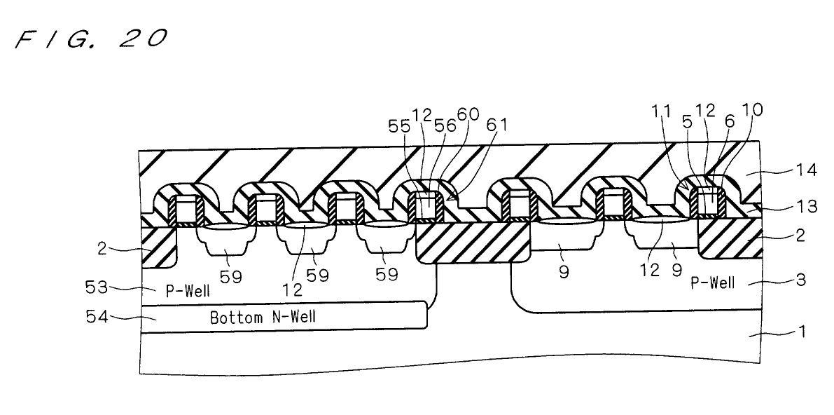

First of all, the steps described with reference to FIGS. 16 to 20 are executed. As a result, a structure shown in FIG. 20 is obtained.

With reference to FIG. 1, next, a stopper film 15 for which a silicon nitride film is employed, for example, is formed on an interlayer insulating film 14.

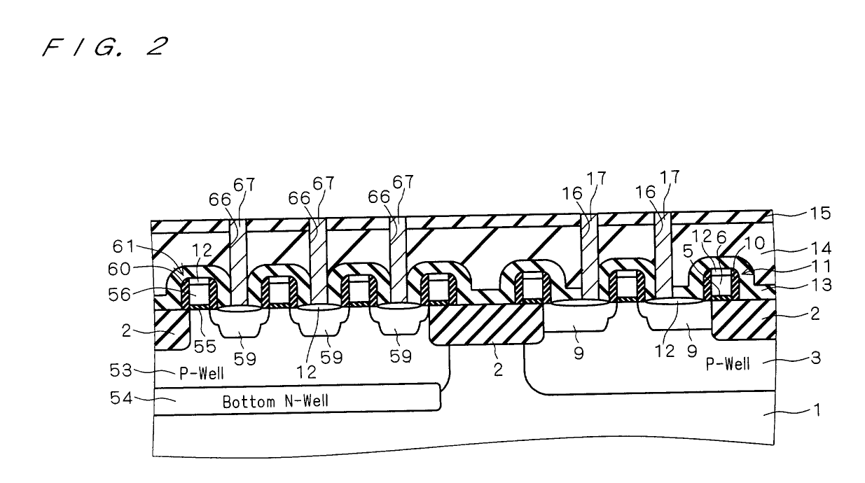

With reference to FIG. 2, thereafter, contact plugs 17 and 67 are formed in the interlayer insulating film 14 and stopper films 13 and 15. Each of the contact plugs 17 is electrically connected to a semiconductor substrate 1 in a logic formation region through a cobalt silicide film 12, and has an upper surface exposed from the stopper film 15. Moreover, each of the contact plugs 67 is electrically connected to the semiconductor substrate 1 in a memory formation region through the cobalt silicide film 12, and has an upper surface exposed from the stopper film 15. A method of manufacturing the contact plugs 17 and 67 will be specifically described below.

First of all, a photoresist (not shown) having a predetermined opening pattern is formed on the stopper film 15 by photolithography. Using the photoresist as a mask, then, the stopper film 15 is removed by etching. At this time, anisotropic dry etching using a mixed gas of CHF₃, O₂ and Ar is employed for the etching, for example.

Thereafter, etching conditions such as the kind of gas to be used are changed and the interlayer insulating film 14 is etched using the photoresist provided on the stopper film 15 as a mask again. At this time, the stopper film 13 functions as an etching stopper. In this case, moreover, a mixing gas of C₅F₈, O₂ and Ar is used in the etching, for example.

Subsequently, the photoresist is removed and etching is carried out on the whole surface, thereby removing the exposed stopper film 13. At this time, the anisotropic dry etching using a mixed gas of CHF₃, O₂ and Ar is employed for the etching. Consequently, contact holes 66 reaching the cobalt silicide film 12 provided on the semiconductor substrate 1 in the memory formation region and contact holes 16 reaching the cobalt silicide film 12 provided on the semiconductor substrate 1 in the logic formation region are formed in the interlayer insulating film 14 and the stopper films 13 and 15. When etching the stopper film 13, the etching is carried out on the whole surface. Therefore, the stopper film 15 is also etched. Accordingly, a thickness of the stopper film 15 is regulated such that a predetermined thickness remains when the etching of the stopper film 13 is completed.

Next, a laminated film comprising a barrier metal layer formed of titanium nitride, for example, and a refractory metal layer formed of titanium, tungsten or the like, is provided over the whole surface with the barrier metal layer to be a lower layer. Then, the laminated film provided on an upper surface of the stopper film 15 is removed by using a CMP method. Consequently, the contact plugs 17 each formed by the barrier metal layer and the refractory metal layer and filling the contact hole 16 are provided, and the contact plugs 67 each formed by the barrier metal layer and the refractory metal layer and filling in the contact hole 66 are provided. As a result, a source/drain region 59 and the contact plug 67 are electrically connected to each other and a source/drain region 9 and the contact plug 17 are electrically connected to each other. A contact plug connected electrically to a gate electrode 56 or a gate electrode 6 through the cobalt silicide film 12 is formed in the interlayer insulating film 14 and the stopper films 13 and 15, which is not shown.

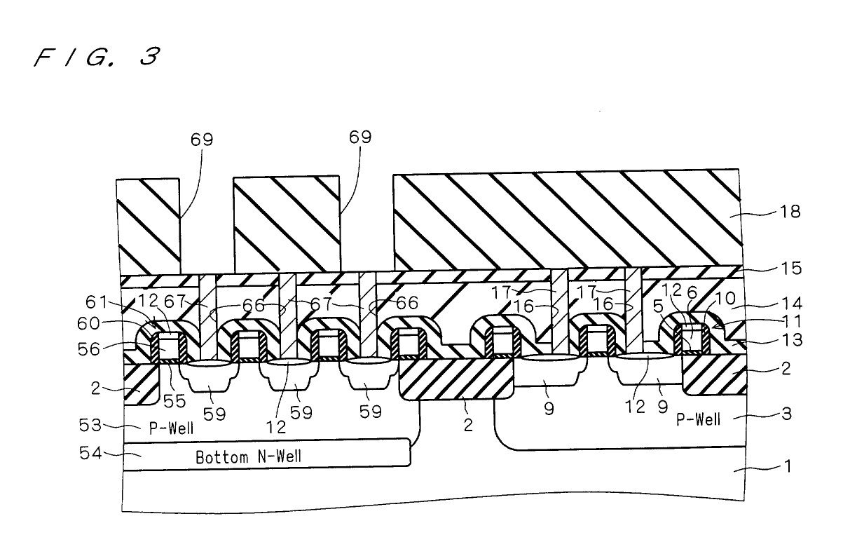

With reference to FIG. 3, next, an interlayer insulating film 18 is formed on the stopper film 15 and the contact plugs 17 and 67. For example, a BPTEOS film is employed for the interlayer insulating film 18. Then, a photoresist (not shown) having a predetermined opening pattern is formed on the interlayer insulating film 18. Using the photoresist as a mask, the interlayer insulating film 18 is etched with the stopper film 15 and the contact plugs 67 serving as an etching stopper to be removed. Thereafter, the photoresist is removed. At this time, anisotropic dry etching using a mixed gas of C₅F₈, O₂ and Ar is employed for the etching. Consequently, opening portions 69 each for exposing the contact plug 67 connected electrically to one of the adjacent source/drain regions 59 are formed in the interlayer insulating film 18. In the etching method to be employed for removing the interlayer insulating film 18, the contact plug 67 is etched with difficulty, and usually, selective ratio between the interlayer insulating film 18 and the contact plug 67 is sufficiently high. In the same manner as the stopper film 15, therefore, the contact plug 67 can be caused to function as an etching stopper and it is possible to prevent the opening portion 69 from reaching the gate electrode 56 or the semiconductor substrate 1.

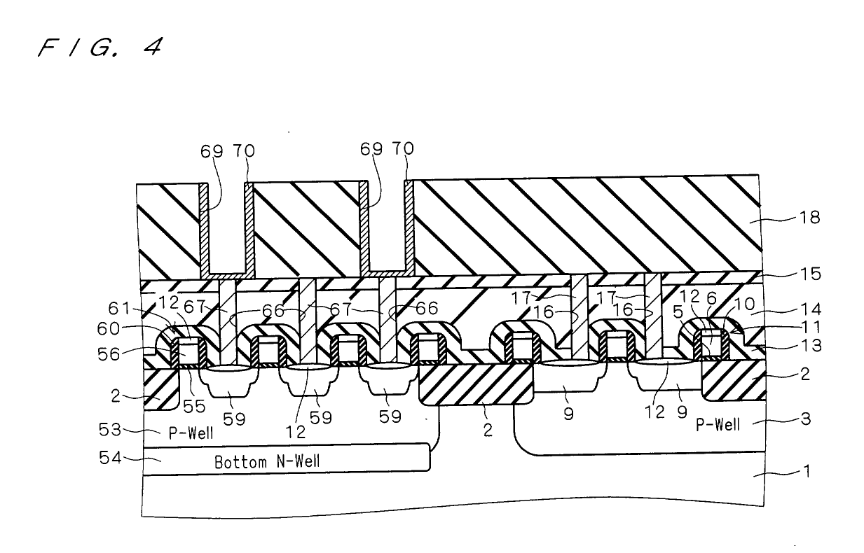

Next, a capacitor 82 of a DRAM memory cell is formed in contact with the contact plug 67 in each of the opening portions 69. More specifically, with reference to FIG. 4, a metal film containing a refractory metal such as ruthenium is first formed over the whole surface. Then, the opening portions 69 are covered with a photoresist (not shown) and the metal film provided on an upper surface of the interlayer insulating film 18 is removed by the anisotropic dry etching. Consequently, a lower electrode 70 of the capacitor containing the refractory metal such as ruthenium is formed in each of the opening portions 69. While the metal film formed on the upper surface of the interlayer insulating film 18 is removed by the anisotropic dry etching, the metal film may be removed by using the CMP method.

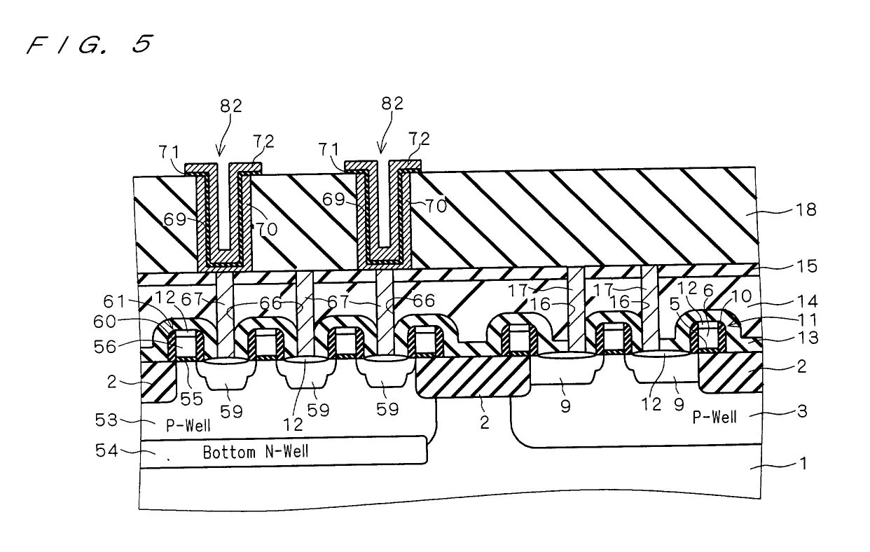

With reference to FIG. 5, subsequently, an insulating film formed of tantalum pentoxide and a metal film containing a refractory metal such as ruthenium are stacked over the whole surface in this order, and they are then subjected to patterning using a photoresist. Consequently, a dielectric film 71 of a capacitor which is formed of tantalum pentoxide and an upper electrode 72 of a capacitor which contains the refractory metal such as ruthenium are provided so that the capacitor 82 is completely formed in each of the opening portions 69.

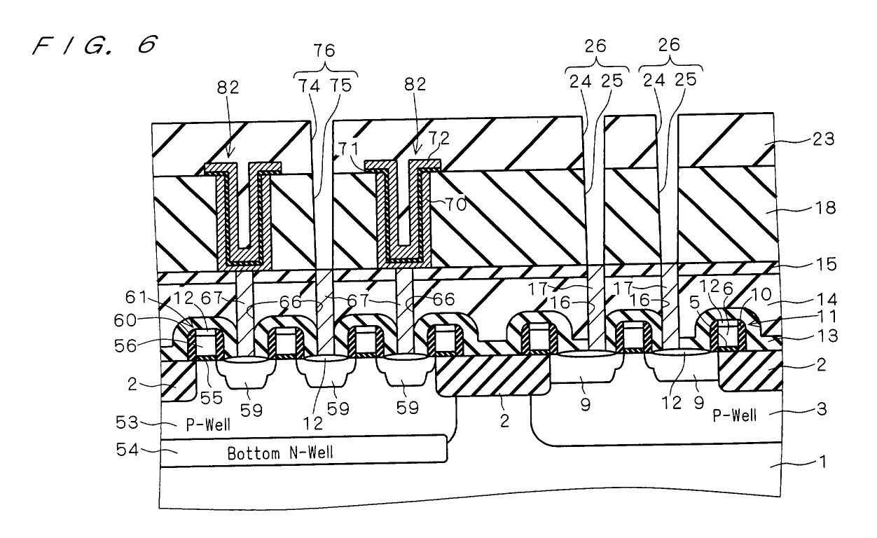

With reference to FIG. 6, subsequently, an interlayer insulating film 23 for which a TEOS film is employed, for example, is formed on the interlayer insulating film 18 to cover the capacitors 82, and is flattened by the CMP method. More specifically, the interlayer insulating film 23 is formed on the upper electrodes 72 of the capacitors 82 and the interlayer insulating film 18 and is flattened. Then, contact holes 26 and 76 are formed in the interlayer insulating films 18 and 23. More specifically, a photoresist (not shown) having a predetermined opening pattern is formed on the interlayer insulating film 23, and the interlayer insulating films 18 and 23 are etched with the stopper film 15 and the contact plugs 17 and 67 serving as an etching stopper to be removed, using the photoresist as a mask. Then, the photoresist is removed. At this time, the anisotropic dry etching using a mixed gas of CHF₃, O₂ and Ar is employed for the etching.

Consequently, the contact holes 26 are formed. Each of the contact holes 26 is constituted by a contact hole 24 reaching an upper surface of the interlayer insulating film 18 from an upper surface of the interlayer insulating film 23 and a contact hole 25 communicating with the contact hole 24 and reaching the contact plug 17 from the upper surface of the interlayer insulating film 18. Furthermore, the contact holes 76 is formed. Each of the contact holes 76 is constituted by a contact hole 74 reaching the upper surface of the interlayer insulating film 18 from the upper surface of the interlayer insulating film 23 and a contact hole 75 communicating with the contact hole 74 and reaching the contact plug 67 which does not contact with the capacitor from the upper surface of the interlayer insulating film 18.

In the etching method to be employed for removing the interlayer insulating films 18 and 23, the contact plugs 17 and 67 are etched with difficulty, and usually, selective ratio between the interlayer insulating films 18 and 23 and the contact plugs 17 and 67 is sufficiently high. Therefore, the contact plugs 17 and 67 can be caused to function as etching stoppers. Moreover, the interlayer insulating film 23 is also provided with a contact hole reaching the upper electrode 72 from the upper surface thereof, which is not shown.

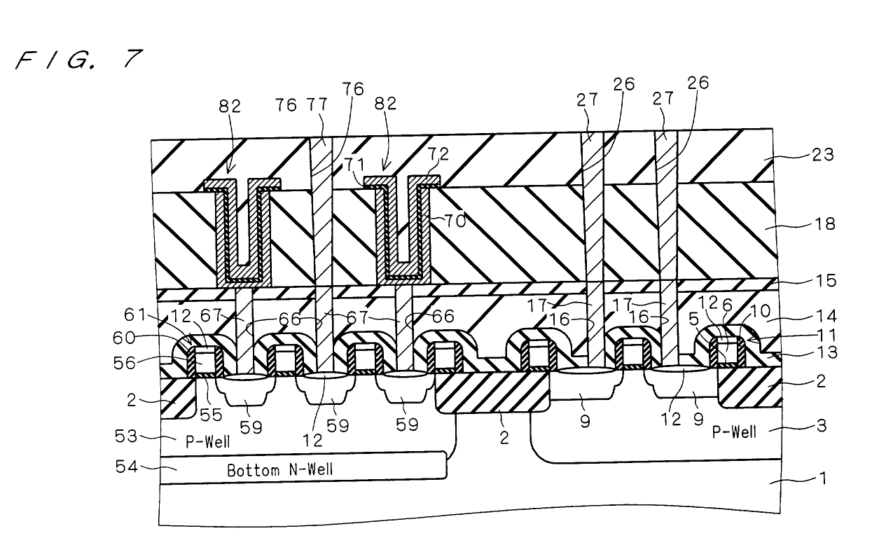

With reference to FIG. 7, next, a laminated film comprising a barrier metal layer formed of titanium nitride and a refractory metal layer formed of titanium or tungsten is provided over the whole surface with the barrier metal layer to be a lower layer. Then, the laminated film provided on the upper surface of the interlayer insulating film 23 is removed by using the CMP method. Consequently, contact plugs 27 each formed by the barrier metal layer and the refractory metal layer and filling the contact hole 26 are provided, and contact plugs 77 each formed by the barrier metal layer and the refractory metal layer and filling the contact hole 76 are provided.

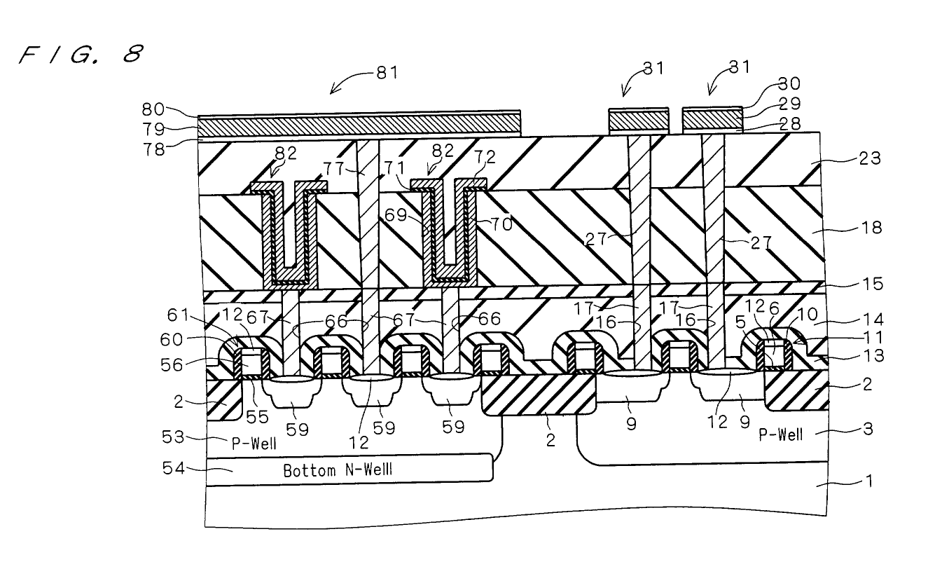

With reference to FIG. 8, subsequently, the interlayer insulating film 23 is provided with a wiring 31 in contact with the contact plug 27 and a wiring 81 in contact with the contact plug 77. The wiring 31 has such a structure that an aluminum wiring 29 is vertically interposed between titanium nitride layers 28 and 30. Moreover, the wiring 81 also has such a structure that an aluminum wiring 79 is vertically interposed between titanium nitride layers 78 and 80 in the same manner as the wiring 31, and is a bit line of a DRAM memory cell.

By the steps described above, the memory device is formed in the memory formation region and the logic device is formed in the logic formation region.

As described above, in the method of manufacturing a semiconductor device according to the first embodiment, when forming the opening portion 69 or the contact holes 26 and 76, only the interlayer insulating film is etched and the step of etching the stopper film is not executed. In the first embodiment, it is necessary to remove the photoresist after etching the interlayer insulating film. Therefore, a change from an etching system to an ashing system is required. Differently from the method of manufacturing a semiconductor device according to the conventional art, it is not necessary to carry out the change from the ashing system to the etching system when forming the opening portion 69 or the contact holes 26 and 76. Consequently, it is possible to shorten a time required for forming the opening portion 69 or the contact holes 26 and 76. As a result, it is possible to shorten a time required for manufacturing the semiconductor device shown in FIG. 8.

If the contents according to the first embodiment are grasped as the contents related to the semiconductor device, moreover, the following is apparent to the semiconductor device shown in FIG. 8, specifically, the semiconductor device comprising the semiconductor substrate 1 having the memory formation region and the logic formation region, the interlayer insulating film 14 formed on the semiconductor substrate 1 through the stopper film 13, the stopper film 15 formed on the interlayer insulating film 14, the contact plug 67 having the upper surface exposed from the stopper film 14 which is electrically connected to the semiconductor substrate 1 in the memory formation region and is formed in the interlayer insulating film 14 and the stopper film 15, the contact plug 17 having the upper surface exposed from the stopper film 15 which is electrically connected to the semiconductor substrate 1 in the logic formation region and is formed in the interlayer insulating film 14 and the stopper film 15, the interlayer insulating film 18 formed on the stopper film 15 and the contact plugs 17 and 67, the opening portion 69 formed on the interlayer insulating film 18 and exposing the contact plug 67, the capacitor 82 formed in the opening portion 69, and the contact hole 25 reaching the contact plug 17 from the upper surface of the interlayer insulating film 18.

The semiconductor device shown in FIG. 8 comprises the contact plug 67 having the upper surface exposed from the stopper film 15 which is electrically connected to the semiconductor substrate 1 in the memory formation region and is formed in the interlayer insulating film 14 and the stopper film 15, and the contact plug 17 having the upper surface exposed from the stopper film 15 which is electrically connected to the semiconductor substrate 1 in the logic formation region and is formed in the interlayer insulating film 14 and the stopper film 15. Therefore, the semiconductor device can be manufactured by the manufacturing method described above. For the above reasons, the time required for the manufacture of the semiconductor device can be shortened.

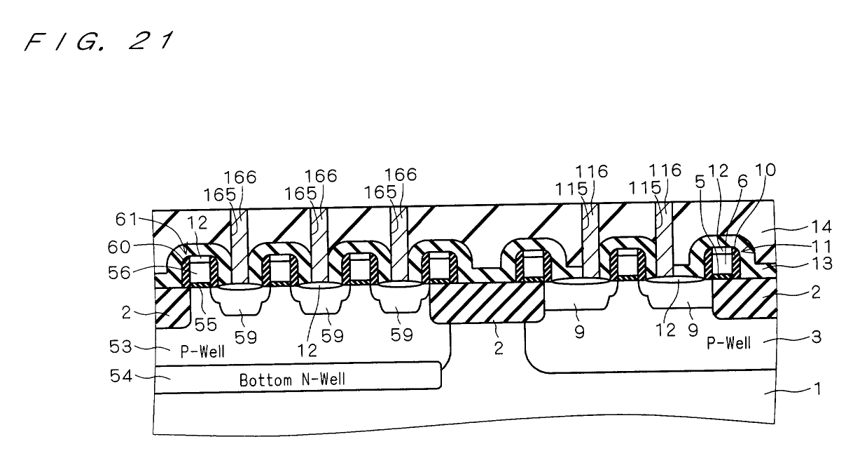

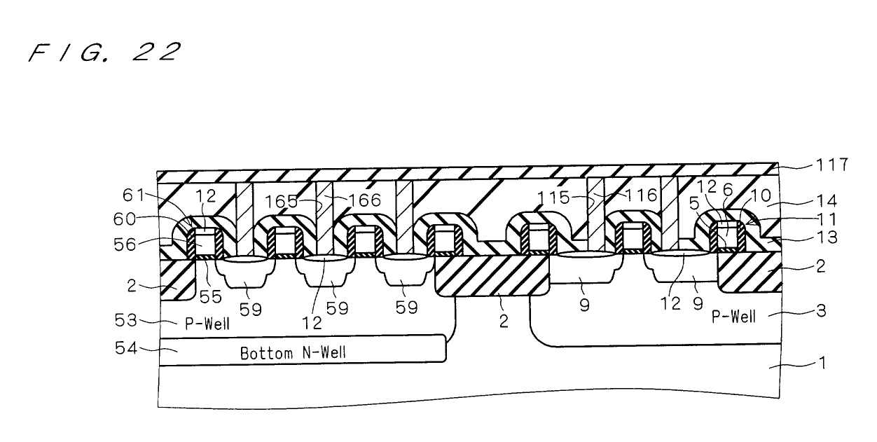

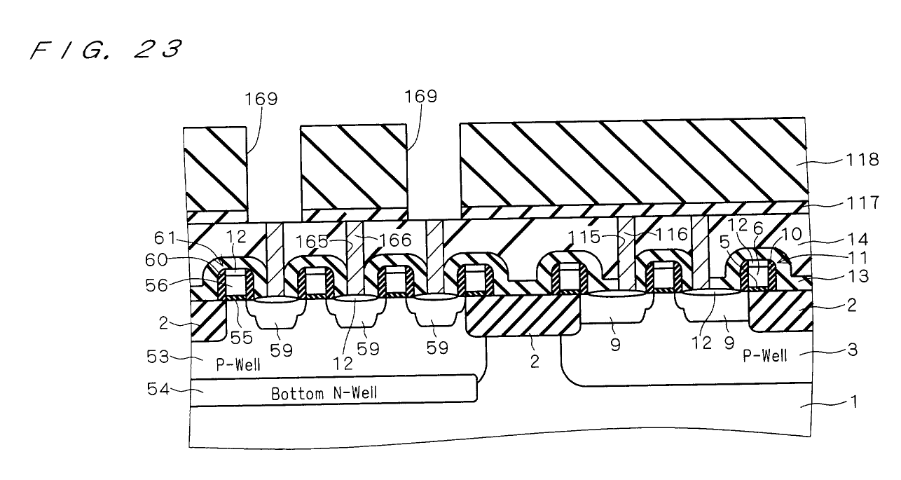

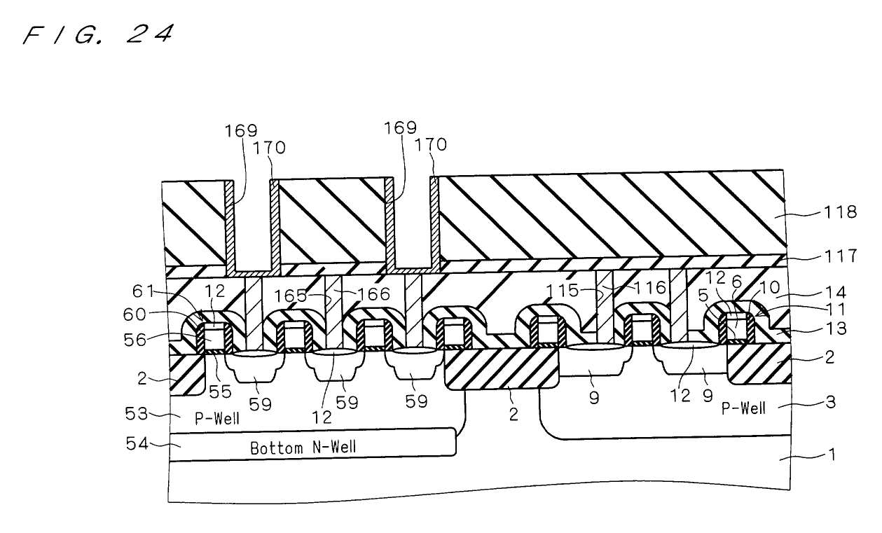

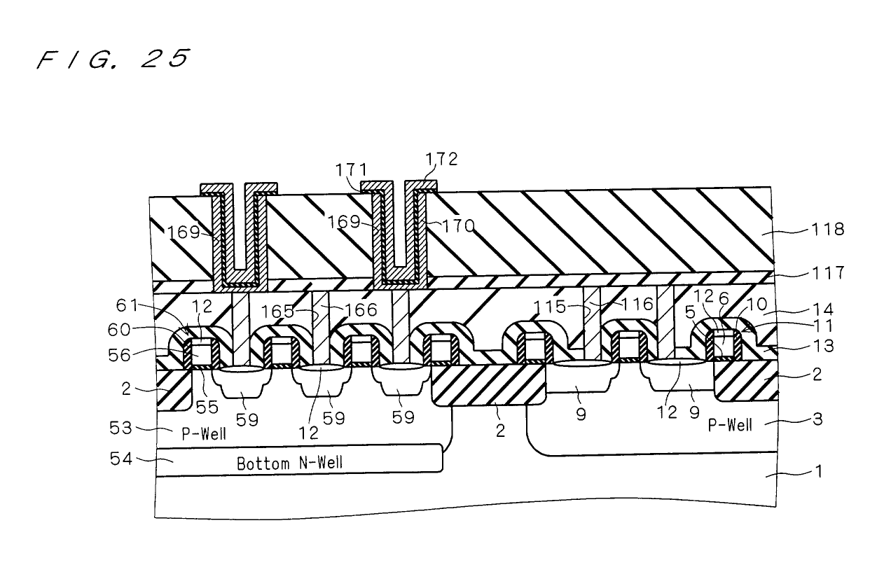

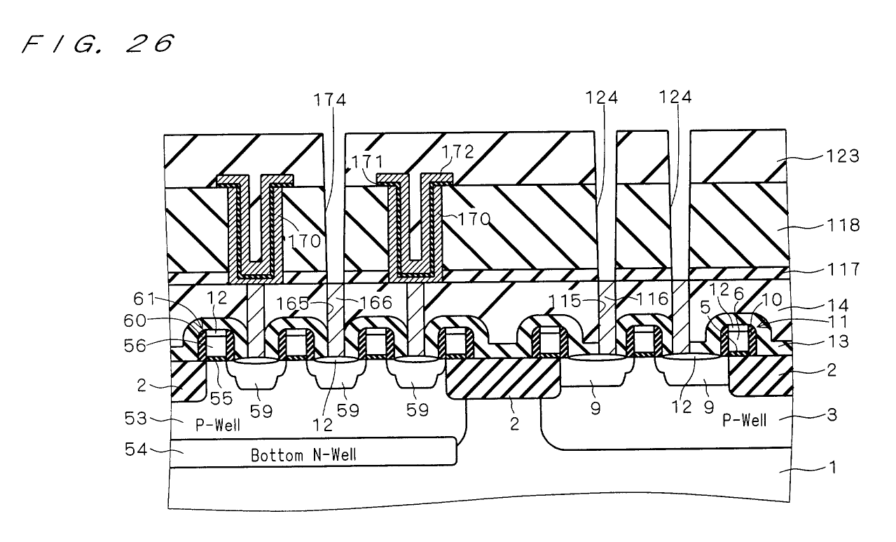

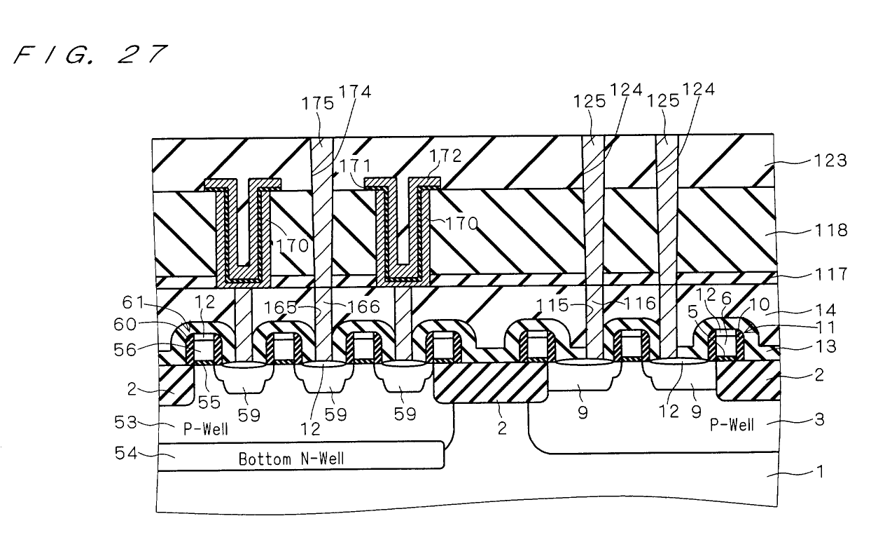

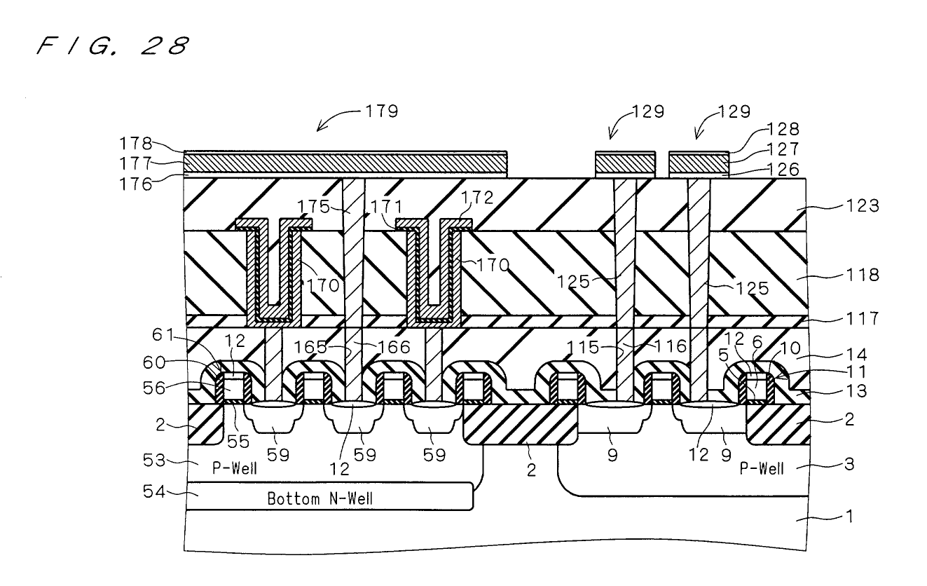

By comparing the step of forming the contact plugs 17 and 67 in the first embodiment (see FIG. 2) with the step of forming the contact plugs 116 and 166 in the method of manufacturing a semiconductor device according to the conventional art (see FIG. 21), it is further necessary to carry out the step of etching the stopper film 15 in the first embodiment. At a subsequent step to the etching of the stopper film 15, however, the interlayer insulating film 14 is etched. Therefore, it is not necessary to change over the manufacturing device. By only changing the etching conditions, it is possible to carry out a change from the step of etching the stopper film 15 into the step of etching the interlayer insulating film 14. Therefore, an increase in the time required for the manufacture which is caused by adding the step of etching the stopper film 15 is much smaller than the above reduction in the time required for the manufacture, and hardly influences a total time required for the manufacture.

Second Embodiment

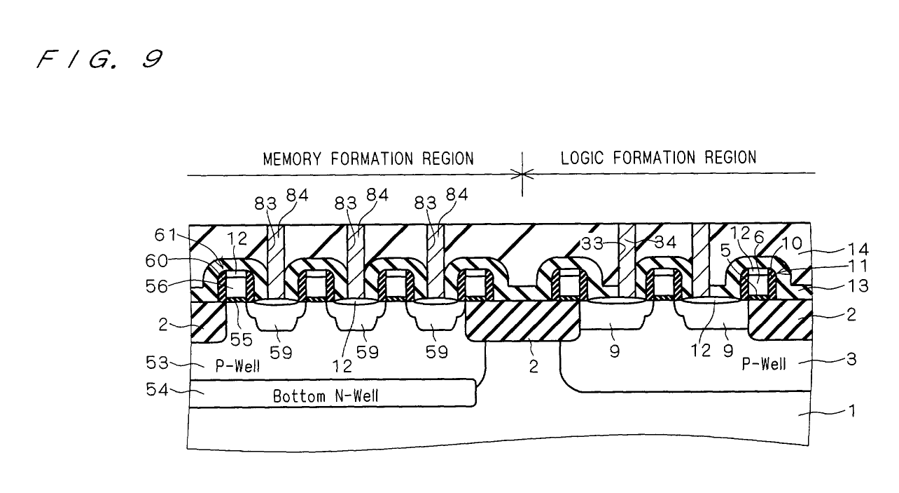

FIGS. 9 to 15 are sectional views showing a method of manufacturing a semiconductor device according to a second embodiment of the present invention in order of steps. The semiconductor device according to the second embodiment is of a memory and logic mixing type, and a DRAM including a memory cell having a CUB structure is employed for a memory device, for example, and a Dual Gate salicide CMOS transistor is employed for a logic device, for example. With reference to FIGS. 9 to 15, the method of manufacturing a semiconductor device according to the second embodiment will be described below.

First of all, the steps described with reference to FIGS. 16 to 20 are executed. As a result, a structure shown in FIG. 20 is obtained.

With reference to FIG. 9, thereafter, contact plugs 34 and 84 are formed in an interlayer insulating film 14 and a stopper film 13. Each of the contact plugs 34 is electrically connected to a semiconductor substrate 1 in a logic formation region through a cobalt silicide film 12, and has an upper surface exposed from the interlayer insulating film 14. Moreover, each of the contact plugs 84 is electrically connected to the semiconductor substrate 1 in the memory formation region through the cobalt silicide film 12, and has an upper surface exposed from the interlayer insulating film 14. A method of manufacturing the contact plugs 34 and 84 will be specifically described below.

First of all, a photoresist (not shown) having a predetermined opening pattern is formed on the interlayer insulating film 14 by photolithography. Using the photoresist as a mask, then, the interlayer insulating film 14 is etched with the stopper film 13 serving as an etching stopper to be removed. At this time, anisotropic dry etching using a mixed gas of C₅F₈, O₂ and Ar is employed for the etching.

Thereafter, the photoresist is removed and the exposed stopper film 13 is removed by etching. At this time, anisotropic dry etching using a mixed gas of CHF₃, O₂ and Ar is employed for the etching. Consequently, contact holes 83 reaching the cobalt silicide film 12 provided on the semiconductor substrate 1 in the memory formation region and contact holes 33 reaching the cobalt silicide film 12 provided on the semiconductor substrate 1 in the logic formation region are formed in the interlayer insulating film 14 and the stopper film 13.

Next, a laminated film comprising a barrier metal layer formed of titanium nitride and a refractory metal layer formed of titanium or tungsten is provided over the whole surface with the barrier metal layer to be a lower layer. Then, the laminated film provided on an upper surface of the interlayer insulating film 14 is removed by using a CMP method. Consequently, the contact plugs 34 each formed by the barrier metal layer and the refractory metal layer and filling the contact hole 33 are provided, and the contact plugs 84 each formed by the barrier metal layer and the refractory metal layer and filling in the contact hole 83 are provided. As a result, a source/drain region 59 and the contact plug 84 are electrically connected to each other and a source/drain region 9 and the contact plug 34 are electrically connected to each other. A contact plug connected electrically to a gate electrode 56 or a gate electrode 6 through the cobalt silicide film 12 is formed in the interlayer insulating film 14 and the stopper film 13, which is not shown.

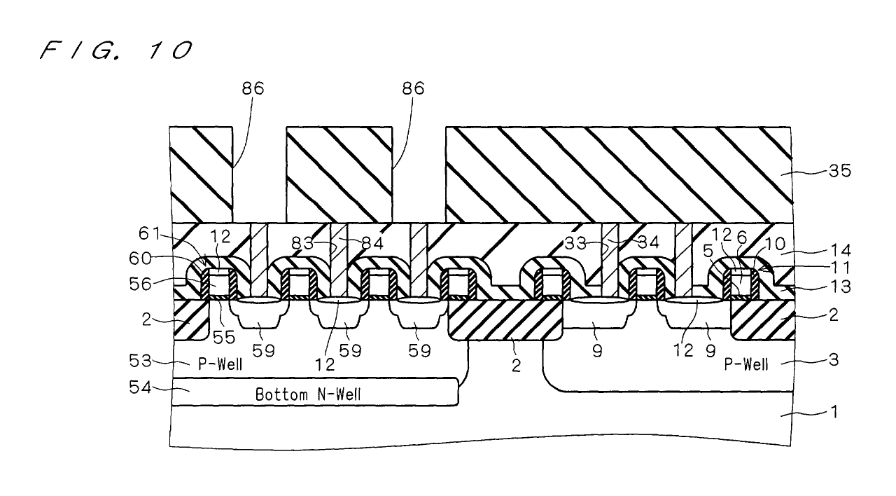

With reference to FIG. 10, next, an interlayer insulating film 35 is formed on the interlayer insulating film 14 and the contact plugs 34 and 84. For example, a BPTEOS film is employed for the interlayer insulating film 35. Then, a photoresist (not shown) having a predetermined opening pattern is formed on the interlayer insulating film 35. Using the photoresist as a mask, the interlayer insulating film 35 is removed by etching. Thereafter, the photoresist is removed. At this time, the anisotropic dry etching using a mixed gas of C₅F₈, O₂ and Ar is employed for the etching. Consequently, opening portions 86 each for exposing the contact plug 84 connected electrically to one of the adjacent source/drain regions 59 are formed in the interlayer insulating film 35.

In the etching method to be employed for removing the interlayer insulating film 35, the contact plug 84 is etched with difficulty, and usually, a selection ratio between the interlayer insulating film 35 and the contact plug 84 is sufficiently high. By enhancing a uniformity of a thickness of the interlayer insulating film 35 and stabilizing an etching rate of the interlayer insulating film 35, moreover, it is possible to reduce an amount of overetching in the etching of the interlayer insulating film 35. Consequently, it is possible to prevent the opening portion 86 from reaching the gate electrode 56 or the semiconductor substrate 1.

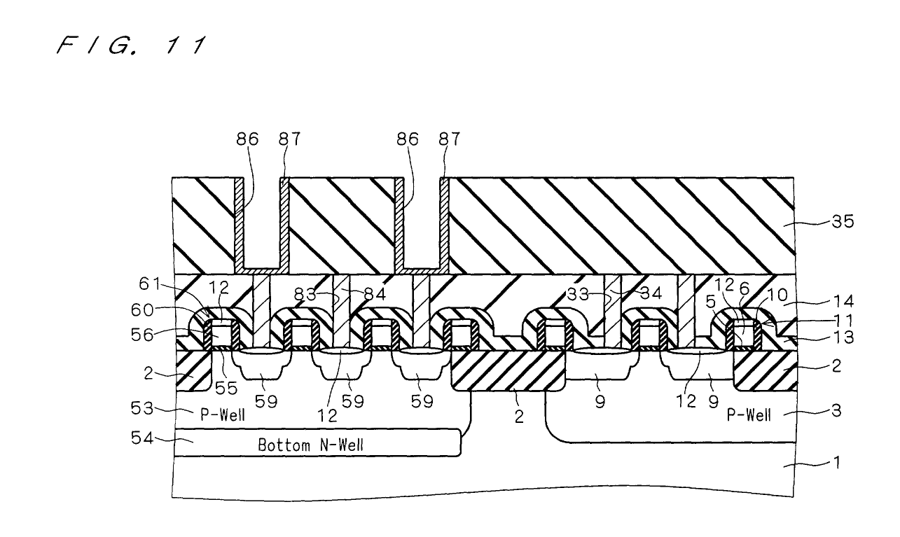

Next, a capacitor 99 of a DRAM memory cell is formed in contact with the contact plug 84 in each of the opening portions 86. More specifically, with reference to FIG. 11, a metal film containing a refractory metal such as ruthenium is first formed over the whole surface. Then, the opening portions 86 are covered with a photoresist (not shown) and the metal film provided on an upper surface of the interlayer insulating film 35 is removed by the anisotropic dry etching. Consequently, a lower electrode 87 of the capacitor containing the refractory metal such as ruthenium is formed in each of the opening portions 86. While the metal film formed on the upper surface of the interlayer insulating film 35 is removed by the anisotropic dry etching, the metal film may be removed by using the CMP method.

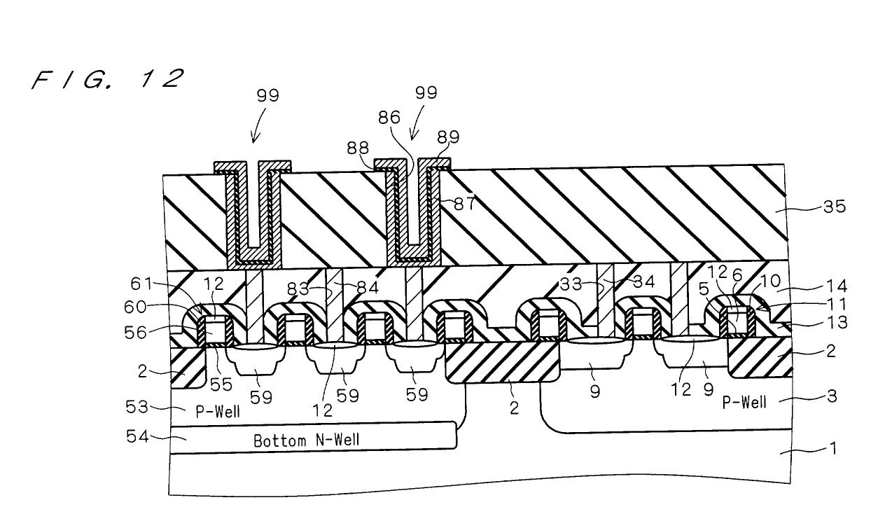

With reference to FIG. 12, subsequently, an insulating film formed of tantalum pentoxide and a metal film containing a refractory metal such as ruthenium are stacked over the whole surface in this order, and they are then subjected to patterning by using a photoresist. Consequently, a dielectric film 88 of a capacitor which is formed of tantalum pentoxide and an upper electrode 89 of a capacitor which contains the refractory metal such as ruthenium are provided so that the capacitor 99 is completely formed in the opening portion 86.

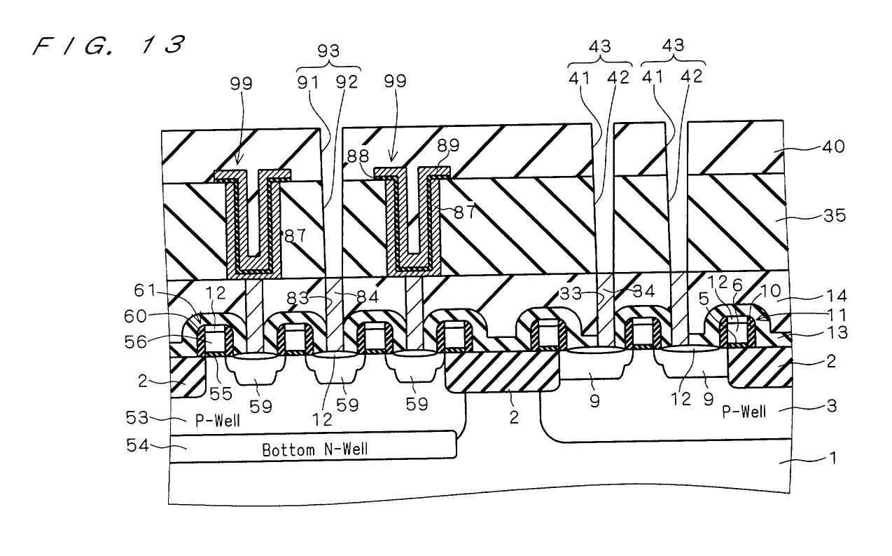

With reference to FIG. 13, subsequently, an interlayer insulating film 40 for which a TEOS film is employed, for example, is formed on the interlayer insulating film 35 to cover the capacitors 99, and is flattened by the CMP method. More specifically, the interlayer insulating film 40 is formed on the upper electrode 89 of the capacitor 99 and the interlayer insulating film 35 and is flattened. Then, contact holes 43 and 93 are formed in the interlayer insulating films 35 and 40. More specifically, a photoresist (not shown) having a predetermined opening pattern is formed on the interlayer insulating film 40, and the interlayer insulating films 35 and 40 are etched and removed by using the photoresist as a mask. Then, the photoresist is removed. At this time, the anisotropic dry etching using a mixed gas of CHF₃, O₂ and Ar is employed for the etching.

Consequently, the contact holes 43 are formed. Each of the contact holes 43 is constituted by a contact hole 41 reaching an upper surface of the interlayer insulating film 35 from an upper surface of the interlayer insulating film 40 and a contact hole 42 communicating with the contact hole 41 and reaching the contact plug 34 from the upper surface of the interlayer insulating film 35. Furthermore, the contact holes 93 are formed. Each of the contact holes 93 is constituted by a contact hole 91 reaching the upper surface of the interlayer insulating film 35 from the upper surface of the interlayer insulating film 40 and a contact hole 92 communicating with the contact hole 91 and reaching the contact plug 84 which does not contact with the capacitor 99 from the upper surface of the interlayer insulating film 35.

In the etching method to be employed for removing the interlayer insulating films 35 and 40, the contact plugs 34 and 84 are etched with difficulty, and usually, a selection ratio between the interlayer insulating films 35 and 40 and the contact plugs 34 and 84 is sufficiently high. By enhancing a uniformity of thicknesses of the interlayer insulating films 35 and 40 and stabilizing etching rates of the interlayer insulating films 35 and 40, moreover, it is possible to reduce an amount of overetching in the etching of the interlayer insulating films 35 and 40. Even if positions in which the contact holes 43 and 93 are to be formed are shifted, consequently, it is possible to prevent the contact holes 43 and 93 from reaching the gate electrode 56 or the semiconductor substrate 1. Moreover, the interlayer insulating film 40 is also provided with a contact hole reaching the upper electrode 89 from the upper surface thereof, which is not shown.

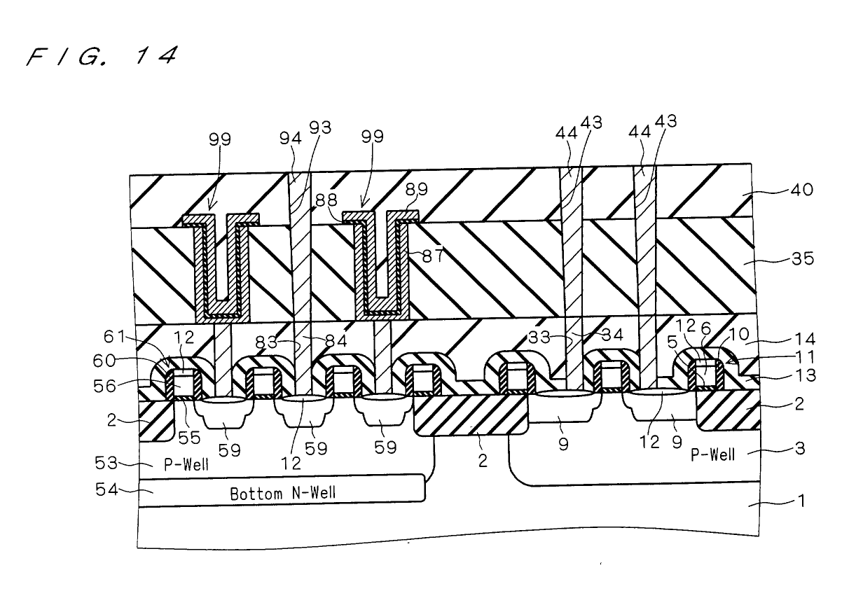

With reference to FIG. 14, next, a laminated film comprising a barrier metal layer formed of titanium nitride, for example, and a refractory metal layer formed of titanium, tungsten or the like, is provided over the whole surface with the barrier metal layer to be a lower layer. Then, the laminated film provided on the upper surface of the interlayer insulating film 40 is removed by using the CMP method. Consequently, contact plugs 44 each formed by the barrier metal layer and the refractory metal layer and filling the contact hole 43 are provided, and a contact plugs 94 each formed by the barrier metal layer and the refractory metal layer and filling the contact hole 93 are provided.

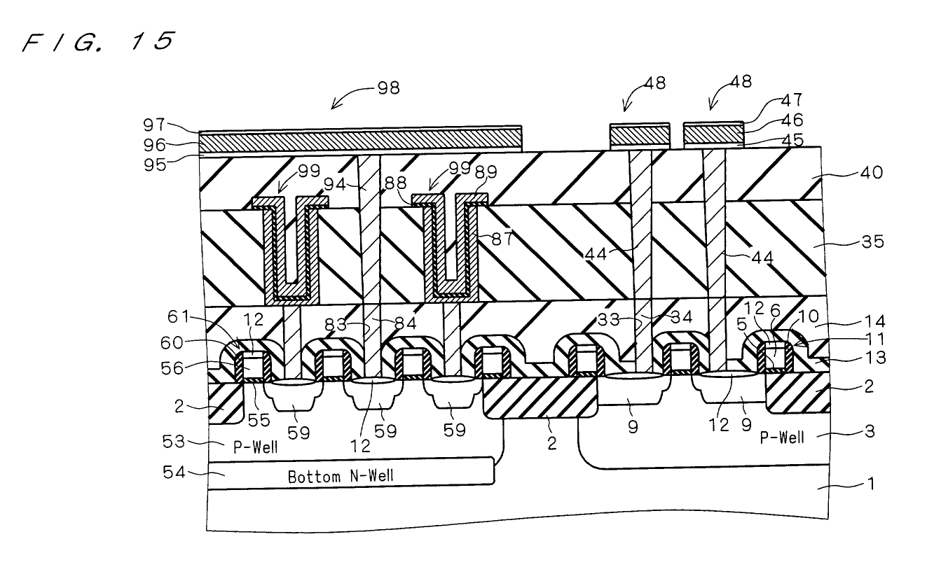

With reference to FIG. 15, subsequently, the interlayer insulating film 40 is provided with a wiring 48 in contact with the contact plug 44 and a wiring 98 in contact with the contact plug 94. The wiring 48 has such a structure that an aluminum wiring 46 is vertically interposed between titanium nitride layers 45 and 47. Moreover, the wiring 98 also has such a structure that an aluminum wiring 96 is vertically interposed between titanium nitride layers 95 and 97 in the same manner as the wiring 48, and is a bit line of a DRAM memory cell.

By the steps described above, the memory device is formed in the memory formation region and the logic device is formed in the logic formation region.

As described above, in the method of manufacturing a semiconductor device according to the second embodiment, when forming the opening portion 86 or the contact holes 43 and 93, only the interlayer insulating film is etched and the step of etching the stopper film is not executed. In the second embodiment, it is necessary to remove the photoresist after etching the interlayer insulating film. For this reason, it is necessary to carry out a change from an etching system to an ashing system. However, it is not necessary to carry out a change from the ashing system to the etching system when forming the opening portion 86 or the contact holes 43 and 93. In such a case, therefore, it is possible to more shorten a time required for forming the opening portion 86 or the contact holes 43 and 93 as compared with the method of manufacturing a semiconductor device according to the conventional art in which the change from the ashing system to the etching system is required. As a result, it is possible to shorten a time required for manufacturing the semiconductor device shown in FIG. 15.

Differently from the method of manufacturing a semiconductor device according to the conventional art and the method of manufacturing a semiconductor device according to the first embodiment, furthermore, the step of forming the stopper film 15 or the stopper film 117 is not required. Therefore, the time required for the manufacture can further be shortened.

If the contents according to the second embodiment are grasped as the contents related to the semiconductor device, moreover, the following is apparent to the semiconductor device shown in FIG. 15, specifically, the semiconductor device comprising the semiconductor substrate 1 having the memory formation region and the logic formation region, the interlayer insulating film 14 formed on the semiconductor substrate 1 through the stopper film 13, the contact plug 84 having the upper surface exposed from the interlayer insulating film 14 which is electrically connected to the semiconductor substrate 1 in the memory formation region and is formed in the interlayer insulating film 14, the contact plug 34 having the upper surface exposed from the interlayer insulating film 14 which is electrically connected to the semiconductor substrate 1 in the logic formation region and is formed in the interlayer insulating film 14, the interlayer insulating film 35 formed on the interlayer insulating film 14 and the contact plugs 34 and 84, the opening portion 86 formed in the interlayer insulating film 35 and exposing the contact plug 84, the capacitor 99 formed in the opening portion 86, and the contact hole 42 reaching the contact plug 34 from the upper surface of the interlayer insulating film 35.

The semiconductor device shown in FIG. 15 comprises the contact plug 84 having the upper surface exposed from the interlayer insulating film 14 which is electrically connected to the semiconductor substrate 1 in the memory formation region and is formed in the interlayer insulating film 14, and the contact plug 34 having the upper surface exposed from the interlayer insulating film 14 which is electrically connected to the semiconductor substrate 1 in the logic formation region and is formed in the interlayer insulating film 14. Therefore, the semiconductor device can be manufactured by the manufacturing method described above. For the above reasons, the time required for the manufacture can be shortened.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device comprising the steps of:
(a) preparing a semiconductor substrate having a first region in which a memory device is to be formed and a second region in which a logic device is to be formed;
(b) forming a first interlayer insulating film on said semiconductor substrate;
(c) forming a stopper film on said first interlayer insulating film;
(d) forming, in said first interlayer insulating film and said stopper film, a first contact plug connected electrically to said semiconductor substrate in said first region and having an upper surface exposed from said stopper film and a second contact plug connected electrically to said semiconductor substrate in said second region and having an upper surface exposed from said stopper film;
(e) forming a second interlayer insulating film on said stopper film and said first and second contact plugs;
(f) etching said second interlayer insulating film with said stopper film and said first contact plug serving as an etching stopper, thereby forming an opening portion for exposing said first contact plug in said second interlayer insulating film;
(g) forming a capacitor in contact with said first contact plug in said opening portion; and
(h) etching said second interlayer insulating film with said stopper film and said second contact plug serving as an etching stopper, thereby forming a first contact hole reaching said second contact plug in said second interlayer insulating film.

2. The method of manufacturing a semiconductor device according to claim 1, wherein said semiconductor substrate prepared in said step (a) has first and second source/drain regions provided apart from each other by a predetermined distance in an upper surface thereof in said first region, and furthermore, has a gate structure on said upper surface thereof between said first and second source/drain regions,
at said step (d), a third contact plug connected electrically to said second source/drain region and having an upper surface exposed from said stopper film is further formed in said first interlayer insulating film and said stopper film,
said first contact plug is formed in an electrical connection to said first source/drain region, and
at said step (e), said second interlayer insulating film is also formed on said third contact plug,
the manufacturing method further comprising the steps of:
(i) forming a third interlayer insulating film on said second interlayer insulating film to cover said capacitor after said step (g) and before said step (h),
at said step (h), said second and third interlayer insulating films being etched with said stopper film and said second contact plug serving as an etching stopper, thereby forming said first contact hole reaching said second contact plug and a second contact hole reaching said third contact plug in said second and third interlayer insulating films,
(j) forming a fourth contact plug to fill in said second contact hole after said step (h); and
(k) forming a bit line on said third interlayer insulating film in contact with said fourth contact plug.

3. A method of manufacturing a semiconductor device, comprising the steps of:
(a) preparing a semiconductor substrate having a first region in which a memory device is to be formed and a second region in which a logic device is to be formed;
(b) forming a first interlayer insulating film on said semiconductor substrate;
(c) forming, in said first interlayer insulating film, a first contact plug connected electrically to said semiconductor substrate in said first region and having an upper surface exposed from said first interlayer insulating film and a second contact plug connected electrically to said semiconductor substrate in said second region and having an upper surface exposed from said first interlayer insulating film;
(d) forming a second interlayer insulating film on said first interlayer insulating film and said first and second contact plugs;
(e) etching said second interlayer insulating film, thereby forming an opening portion for exposing said first contact plug in said second interlayer insulating film;
(f) forming a capacitor in contact with said first contact plug in said opening portion; and
(g) etching said second interlayer insulating film, thereby forming a first contact hole reaching said second contact plug in said second interlayer insulating film.

4. The method of manufacturing a semiconductor device according to claim 3, wherein said semiconductor substrate prepared in said step (a) has first and second source/drain regions provided apart from each other by a predetermined distance in an upper surface thereof in said first region, and furthermore, has a gate structure on said upper surface thereof between said first and second source/drain regions,
at said step (c), a third contact plug connected electrically to said second source/drain region and having an upper surface exposed from said first interlayer insulating film is further formed in said first interlayer insulating film,
said first contact plug is formed in an electrical connection to said first source/drain region, and
at said step (d), said second interlayer insulating film is also formed on said third contact plug,
the manufacturing method further comprising the steps of:
(h) forming a third interlayer insulating film on said second interlayer insulating film to cover said capacitor after said step (f) and before said step (g),
at said step (g), said second and third interlayer insulating films being etched, thereby forming said first contact hole reaching said second contact plug and a second contact hole reaching said third contact plug in said second and third interlayer insulating films,
(i) forming a fourth contact plug to fill in said second contact hole after said step (g); and
(j) forming a bit line on said third interlayer insulating film in contact with said fourth contact plug.

5. The method of manufacturing a semiconductor device according to claim 1, wherein each of said first and second interlayer insulating films is formed by a silicon oxide film,
said stopper film is formed by a silicon nitride film, and
each of said first and second contact plugs is formed by a metal film.

6. The method of manufacturing a semiconductor device according to claim 3, wherein each of said first and second interlayer insulating films is formed by a silicon oxide film, and
each of said first and second contact plugs is formed by a metal film.
